(19) United States
(12) Patent Application Publication
(10) Pub. No.: US 2025/0253165 A1
(43) Pub. Date: Aug. 7, 2025

(54) DRY CLEANING APPARATUS

(71) Applicant: Samsung Electronics Co., Ltd., Suwon-si (KR)

(72) Inventors: Chanyeong Jeong, Suwon-si (KR); Sunggil Kang, Suwon-si (KR); Jeasung Ryu, Suwon-si (KR); Seokyoung Park, Suwon-si (KR); Sungyong Park, Suwon-si (KR); Hangyul Lee, Suwon-si (KR); Inhye Jeong, Suwon-si (KR); Hyunwoo Jo, Suwon-si (KR); Junhyeok Choi, Suwon-si (KR)

(21) Appl. No.: 18/807,463

(22) Filed: Aug. 16, 2024

(30) Foreign Application Priority Data
Feb. 7, 2024 (KR) 10-2024-0018576

(51) Int. Cl. H01L 21/67; H01J 37/32; H01L 21/687

(52) U.S. Cl. CPC H01L 21/67034; H01J 37/32091; H01J 37/32174; H01J 37/3244; H01J 37/32724; H01L 21/68742; H01L 21/6875; H01J 2237/335

(57) ABSTRACT

A dry cleaning apparatus may include a cleaning chamber, at least two dry cleaning modules, and a power supply. The at least two dry cleaning modules may be stacked in the cleaning chamber and configured to separately dry clean at least two substrates at the same time. The power supply may supply power individually to the at least two dry cleaning modules to generate plasma for dry cleaning each of the at least two substrates. Thus, the dry cleaning modules may receive independent power from the power supply so that each of the substrates may be drying cleaned under the same conditions. As a result, the time to clean the boards is significantly reduced, which may improve the productivity of semiconductor devices.

### CROSS-RELATED APPLICATION

This application claims priority under 35 USC § 119 to Korean Patent Application No. 10-2024-0018576, filed on Feb. 7, 2024, in the Korean Intellectual Property Office (KIPO), the contents of which are herein incorporated by reference in their entirety.

### BACKGROUND

### 1. Field

Example embodiments relate to a dry cleaning apparatus. More specifically, example embodiments relate to a dry cleaning apparatus configured to clean a plurality of substrates simultaneously and/or in parallel.

### 2. Description of the Related Art

To remove contaminants from a substrate, the substrate may be wet cleaned using a cleaning solution. However, the cleaning solution may not be able to penetrate into the micro-patterns of the substrate and remove contaminants within the micro-patterns. To overcome this limitation of wet cleaning, the substrate may be cleaned by dry cleaning using a cleaning gas.

According to the related art, a dry cleaning apparatus may clean only one substrate at a time. Thus, the time required to clean multiple substrates may be prolonged. As a result, the productivity of a semiconductor device manufacturing process may be reduced.

### SUMMARY

Example embodiments provide a dry cleaning device that may be capable of dry cleaning a plurality of substrates simultaneously to significantly reduce the cleaning time for the plurality of substrates.

According to example embodiments, there may be provided a dry cleaning apparatus. The dry cleaning apparatus may include a cleaning chamber, at least two dry cleaning modules, and a supply. The at least two dry cleaning modules may be configured to separately dry clean at least two substrates at the same time. The power supply may supply power individually to the at least two dry cleaning modules to generate a plasma for dry cleaning each of the at least two substrates.

According to example embodiments, there may be provided a dry cleaning apparatus. The dry cleaning apparatus may include a cleaning chamber, a first support, a first lower conductive plate, a first heater, a second support, a first upper conductive plate, a second heater, a first showerhead, a second lower conductive plate, a second upper conductive plate, a second showerhead, a first power supply, and a second power supply. The first support may be disposed in the cleaning chamber and having a support surface to support a first substrate. The first lower conductive plate may be disposed in the first support. The first heater may be sposed in the first support to heat the first substrate. The second support may be disposed in the cleaning chamber over the first support to support a second substrate. The first upper conductive plate may be disposed in the second support. The second heater may be disposed in the second support and heat the second substrate. The first showerhead may be disposed on a lower surface of the second support and introduce a reaction gas for plasma formation between the first lower conductive plate and the first upper conductive plate. The second lower conductive plate may be disposed in the second support over the first upper conductive plate. The second upper conductive plate may be disposed over the second lower conductive plate. The second showerhead may be disposed under the second upper conductive plate to introduce a reaction gas for plasma formation between the second lower conductive plate and the second upper conductive plate. The first power supply may selectively supply a first power to the first lower conductive plate and the second lower conductive plate to cause the first and second lower conductive plates to selectively operate as one of an electrode and a ground. The second power supply may selectively supply a second power to the first upper conductive plate and the second upper conductive plate to cause the first and second upper conductive plates to selectively operate as one of an electrode and a ground. When the first lower conductive plate and the second lower conductive plate operate as electrodes, the first upper conductive plate and the second upper conductive plate operate as the ground, and when the first lower conductive plate and the second lower conductive plate operate as the ground, the first upper conductive plate and the second upper conductive plate operate as electrodes.

According to example embodiments, the dry cleaning modules may be provided with independent power from the power supply so that each of the substrates may be dry cleaned under the same conditions. In particular, the upper and lower conductive plates may be operated as an electrode or a ground depending on which conduction plate is powered, allowing precise control of the plasma generated within the dry cleaning modules. As a result, the time to clean the substrates may be significantly reduced, which may improve the productivity of a semiconductor device process.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is a schematic, cross-sectional view illustrating a dry cleaning apparatus in accordance with example embodiments;

FIG. 2 is an enlarged schematic, cross-sectional view illustrating dry cleaning modules of the dry cleaning apparatus shown in FIG. 1;

FIG. 3 is a schematic, cross-sectional view taken along a line A-A′ in FIG. 2;

FIGS. 4 and 5 are schematic, cross-sectional views illustrating an operation of loading substrates in the dry cleaning apparatus shown in FIG. 1;

FIG. 6 is a schematic, cross-sectional view illustrating an operation of dry cleaning substrates using a direct plasma;

FIG. 7 is a schematic, cross-sectional view illustrating an operation of dry cleaning substrates using a remote plasma; and

FIGS. 8 and 9 are schematic, cross-sectional views illustrating an operation of unloading substrates from the dry cleaning apparatus shown in FIG. 1.

### DETAILED DESCRIPTION OF THE EMBODIMENTS

Hereinafter, example embodiments will be explained in detail with reference to the accompanying drawings. The invention may, however, be embodied in many different forms and should not be construed as limited to the example embodiments set forth herein.

In the following description, the term “substrate” may denote a substrate itself, or a stack structure including a substrate and predetermined layers or films formed on a surface of the substrate. In addition, the term “surface of a substrate” may denote an exposed surface of the substrate itself, or an external surface of a predetermined layer or a film formed on the substrate.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal and/or electrical power can be transferred from one component to the other (although such electrical signal or power may be attenuated in strength as it is transferred and may be selectively transferred). In the following description, materials or items described as “conductive” conduct electricity, and materials or items described as “insulative” do not readily conduct electricity.

It will be appreciated that “planarization,” “co-planar,” “planar,” etc., as used herein refer to structures (e.g., surfaces) that need not be perfectly geometrically planar but may include acceptable variances that may result from standard manufacturing processes.

Throughout the specification, when a component is described as “including” a particular element or group of elements, it is to be understood that the component is formed of only the element or the group of elements, or the element or group of elements may be combined with additional elements to form the component unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

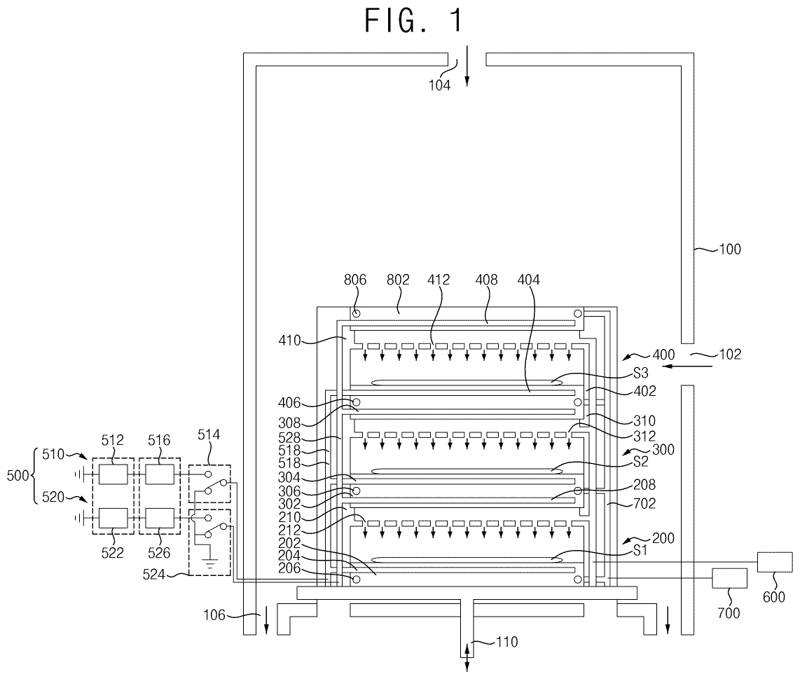

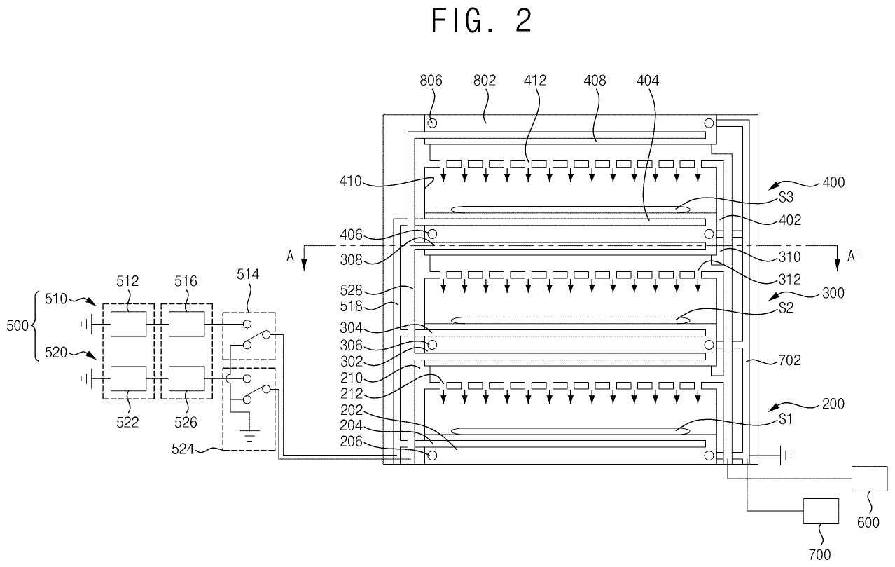

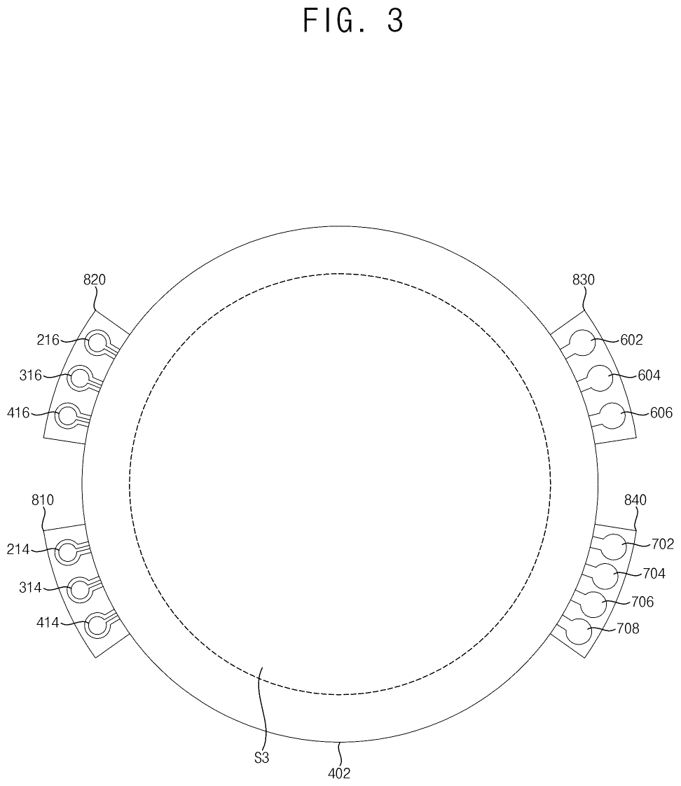

FIG. 1 is a schematic cross-sectional view illustrating a dry cleaning apparatus in accordance with example embodiments, and FIG. 2 is an enlarged schematic cross-sectional view illustrating dry cleaning modules of the dry cleaning apparatus shown in FIG. 1 and FIG. 3 is a schematic cross-sectional view taken along line A-A′ in FIG. 2.

Referring to FIGS. 1 to 3, a dry cleaning apparatus of example embodiments may dry clean a substrate or other item. More specifically, the dry cleaning apparatus may dry clean a semiconductor substrate using plasma. In particular, the dry cleaning apparatus may dry clean a plurality of semiconductor substrates simultaneously. The dry cleaning apparatus may include a cleaning chamber 100, a lifter 110, first, second, and third dry cleaning modules 200, 300, 400, and a power supply 500.

The cleaning chamber 100 may receive therein, or house, the first, second, and third dry cleaning modules 200, 300, and 400. For example, the cleaning chamber 100 may have a cylindrical, cuboidal shape, or the like, but is not limited thereto. In example embodiments, the cleaning chamber 100 may include a substrate entrance 102, a gas port 104, and an exhaust port 106. In some embodiments, the cleaning chamber 100 may include a substrate exit in addition to the substrate entrance 102, or the substrate exit may be the same as the substrate entrance 102.

The semiconductor substrates may be introduced into, or removed from, the cleaning chamber 100 through the substrate entrance 102. The substrate entrance 102 may be formed in the middle of a sidewall of the cleaning chamber 100, but is not limited thereto. For example, the substrate entrance 102 may be formed at an upper or lower portion of a sidewall of the cleaning chamber 100. In embodiments having a substrate exit, the substrate exit may be formed at the same height as the substrate entrance 102 or at a different height. The substrate exit may be formed in the same sidewall as the substrate entrance 102, or on a different sidewall.

The gas port 104 may be formed on the upper surface of the cleaning chamber 100 and may penetrate through a wall of the cleaning chamber 100. A non-reactive gas (inert gas) may be introduced into the cleaning chamber 100 through the gas port 104. The inert gas may regulate the concentration of the reactant gas for plasma formation, assisting in plasma generation, or evacuating reaction byproducts within the cleaning chamber 100. The non-reactive gas may include, but is not limited to, a purge gas which may be an inert gas, such as nitrogen gas.

The exhaust port 106 may be formed on a lower surface of the cleaning chamber 100 and may penetrate through a wall of the cleaning chamber 100. The exhaust port 106 may be connected to a vacuum pump. The reaction byproducts may be evacuated from the cleaning chamber 100 through the exhaust port 106 by a vacuum provided by the vacuum pump.

The lifter 110 may elevate the first, second, and third dry cleaning modules 200, 300, and 400 to different heights. In particular, the lifter 110 may selectively position each of the first, second, and third dry cleaning modules 200, 300, and 400 at a height of the substrate entrance 102, i.e., the lifter 110 may position each of the first, second, and third dry cleaning modules 200, 300 and 400 at a substrate-loading height and a substrate-unloading height. For example, the lifter 110 may be an elevator having a linearly extending shaft coupled to an actuator configured to selectively move the shaft upward and downward. The actuator may be controlled by a controller which may control other aspects of the dry cleaning apparatus. The substrate-loading height and the substrate-unloading height may correspond to the height of the substrate entrance 102. Thus, the substrate-loading height and the substrate-unloading height may be the same.

The first, second, and third dry cleaning modules 200, 300, and 400 may be disposed on an upper surface of the lifter 110. In particular, the first, second, and third dry cleaning modules 200, 300, and 400 may be stacked sequentially on the upper surface of the lifter 110. For example, the first dry cleaning module 200 may be disposed on the upper surface of the lifter 110, the second dry cleaning module 300 may be disposed on an upper surface of the first dry cleaning module 200W, and the third dry cleaning module 400 may be disposed on an upper surface of the second dry cleaning module 300. In some example embodiments, the dry cleaning modules may be embodied as the three dry cleaning modules, but the number of dry cleaning modules is not limited thereto. For example, the dry cleaning module may include two dry cleaning modules or four or more dry cleaning modules.

The first, second, and third dry cleaning modules 200, 300, and 400 may each dry clean one of the semiconductor substrates separately. For example, the first dry cleaning module 200 may dry clean the first semiconductor substrate S1, the second dry cleaning module 300 may dry clean the second semiconductor substrate S2, and the third dry cleaning module 400 may dry clean the third semiconductor substrate S3. Thus, each of the first, second, and third dry cleaning modules 200, 300, and 400 may have or form a batch type structure for cleaning one semiconductor substrate.

The first dry cleaning module 200 may include a first support 202, a first lower conductive plate 204, a first heater 206, a second support 302, a first upper conductive plate 208, and a first showerhead 210.

The first support 202 may be disposed on an upper surface of the lifter 110. For example, the first support 202 may be disposed on and may contact the upper surface of the lifter 110. The first support 202 may support the first semiconductor substrate S1. For example, the first semiconductor substrate S1 may be arranged on and may contact the upper surface of the first support 202. Thus, the first support 202 may operate as a stage. The first support 202 may include an insulating material.

The first lower conductive plate 204 may be disposed in the first support 202. The first lower conductive plate 204 may operate as an electrode or as a ground for the power supply 500. When the first lower conductive plate 204 operates as the electrode, the first lower conductive plate 204 may correspond to a lower electrode of the first dry cleaning module 200.

The first heater 206 may be disposed in the first support 202. The first heater 206 may heat the first semiconductor substrate S1 on the top surface of the first support 202, i.e., heat generated by the first heater 206 may be transferred through the first support 202 to the first semiconductor substrate S1, causing the first semiconductor substrate S1 to be heated. The first heater 206 may be located under the first lower conductive plate 204, but is not limited thereto. Further, the first heater 206 may include, but is not limited to, a coil heater.

The second support 302 may be disposed over the first support 202 and may be spaced apart from the first support 202. Thus, a space may be formed between the first support block 202 and the second support 302. The second support 302 may include an insulating material.

The first upper conductive plate 208 may be disposed in the second support 302. The first upper conductive plate 208 may operate as an electrode or may operate as a ground for the power supply 500. When the first upper conductive plate 208 operates as the electrode, the first upper conductive plate 208 may correspond to an upper electrode of the first dry cleaning module 200.

The first showerhead 210 may be disposed on a lower surface of the second support 302. Accordingly, a space between the first support 202 and the second support 302 may be compartmentalized and/or divided by the first showerhead 210 into an upper space and a lower space. The upper space may be formed between the first showerhead 210 and the second support 302. The lower space may be formed between the first showerhead 210 and the first support 202. A reaction gas may be introduced into the upper space between the first showerhead 210 and the second support 302. The first showerhead 210 may include a plurality of first injection holes 212 configured to inject the reaction gas or plasma. The first injection holes 212 may be formed in the first showerhead 210 along a direction substantially perpendicular or perpendicular to the lower surface of the first showerhead 210. In example embodiments, the first showerhead 210 may include a conductive material, such as metal.

The second dry cleaning module 300 may include the second support 302, a second lower conductive plate 304, a second heater 306, a third support 402, a second upper conductive plate 308, and a second showerhead 310.

In example embodiments, the second dry cleaning module 300 may share the second support 302 with the first dry cleaning module 200. Alternatively, the second support 302 may be replaced by an upper support and a lower support, and the second dry cleaning module 300 may include the upper support to replace the second support 302 and the first dry cleaning module 200 may include the lower support to replace the second support 302.

The second support 302 may support the second semiconductor substrate S2, i.e., the second semiconductor substrate S2 may be arranged on the upper surface of the second support 302. Thus, the second support 302 may operate as a stage. The second support 302 may include an insulating material.

The second lower conductive plate 304 may be disposed in the second support 302. In particular, the second lower conductive plate 304 may be disposed over the first upper conductive plate 208. The second lower conductive plate 304 may operate as an electrode or as a ground for the power supply 500. When the second lower conductive plate 304 operates as the electrode, the second lower conductive plate 304 may correspond to a lower electrode of the second dry cleaning module 300.

The second heater 306 may be disposed in the second support 302. In particular, the second heater 306 may be positioned between the first upper conductive plate 208 and the second lower conductive plate 304. The second heater 306 may heat the second semiconductor substrate S2 on the top surface of the second support 302, i.e., the heat generated by the second heater 306 may be transferred through the second support 302 to the second semiconductor substrate S2, causing the second semiconductor substrate S2 to be heated. The second heater 306 may include, but is not limited to, a coil heater.

The third support 402 may be disposed over the second support 302 and may be spaced apart from the second support 302. Thus, a space may be formed between the second support 302 and the third support 402. The third support 402 may include an insulating material.

The second upper conductive plate 308 may be disposed in the third support 402. The second upper conductive plate 308 may operate as an electrode or as a ground for the power supply 500. When the second upper conductive plate 308 operates as the electrode, the second upper conductive plate 308 may correspond to an upper electrode of the second dry cleaning module 300.

The second showerhead 310 may be disposed on a lower surface of the third support 402. Accordingly, a space between the second support 302 and the third support 402 may be compartmentalized and/or divided by the second showerhead 310 into an upper space and a lower space. The upper space may be formed between the second showerhead 310 and the third support 402. The lower space may be formed between the second showerhead 310 and the second support 302. The reaction gas may be introduced into the upper space between the second showerhead 310 and the third support 402. The second showerhead 310 may include second injection holes 312 configured to inject the reaction gas or plasma. The second injection holes 312 may be formed in the second showerhead 310 along a direction substantially perpendicular or perpendicular to the lower surface of the second showerhead 310. In example embodiments, the second showerhead 310 may include a conductive material, such as metal.

The third dry cleaning module 400 may include a third support 402, a third lower conductive plate 404, a third heater 406, a fourth support 802, a third upper conductive plate 408, and a third showerhead 410.

In example embodiments, the third dry cleaning module 400 may share the third support 402 with the second dry cleaning module 300. Alternatively, the third support 402 may be replaced by an upper and a lower, and the third dry cleaning module 400 may include the upper to replace the third support 402 and the second dry cleaning module 300 may include the lower to replace the third support 402.

The third support 402 may support the third semiconductor substrate S3, i.e., the third semiconductor substrate S3 may be arranged on and/or contact the upper surface of the third support 402. Thus, the third support 402 may operate as a stage. The third support 402 may include an insulating material.

The third lower conductive plate 404 may be disposed in the third support 402. In particular, the third lower conductive plate 404 may be disposed over the second upper conductive plate 308. The third lower conductive plate 404 may operate as an electrode or as a ground for the power supply 500. When the third lower conductive plate 404 operates as the electrode, the third lower conductive plate 404 may correspond to a lower electrode of the third dry cleaning module 400.

The third heater 406 may be disposed in the third support 402. In particular, the third heater 406 may be positioned between the second upper conductive plate 308 and the third lower conductive plate 404. The third heater 406 may heat the third semiconductor substrate S3 on the top surface of the third support 402, i.e., heat generated by the third heater 406 may be transferred through the third support 402 to the third semiconductor substrate S3, causing the third semiconductor substrate S3 to be heated. The third heater 406 may include, but is not limited to, a coil heater.

The fourth support 802 may be disposed over the third support 402 and may be spaced apart from the third support 402. Thus, a space may be formed between the third support 402 and the fourth support 802. The fourth support 802 may include an insulating material.

The third upper conductive plate 408 may be disposed in the fourth support 802. The third upper conductive plate 408 may operate as an electrode or as a ground for the power supply 500. When the third upper conductive plate 408 operates as the electrode, the third upper conductive plate 408 may correspond to an upper electrode of the third dry cleaning module 400.

The third showerhead 410 may be disposed on a lower surface of the fourth support 802. Accordingly, a space between the third support 402 and the fourth support 802 may be compartmentalized and/or divided by the third showerhead 410 into an upper space and a lower space. The upper space may be formed between the third showerhead 410 and the fourth support 802. The lower space may be formed between the third showerhead 410 and the third support 402. The reaction gas may be introduced into the upper space between the third showerhead 410 and the fourth support 802. The third showerhead 410 may include third injection holes 412 that inject the reaction gas or plasma. The third injection holes 412 may be formed in the third showerhead 410 along a direction perpendicular to the lower surface of the third showerhead 410. In example embodiments, the third showerhead 410 may include a conductive material, such as metal.

Additionally, a fourth heater 806 may be disposed in the fourth support 802. The fourth heater 806 may be positioned over the third upper conductive plate 408.

The power supply 500 may selectively supply a first power such as radio frequency power (RF power), to the first, second, and third lower conductive plates 204, 304, and 404 and the first, second, and third upper conductive plates 208, 308, and 408. The power supply 500 may include a first power supply 510 and a second power supply 520.

The first power supply 510 may supply first power to the first, second, and third lower conductive plates 204, 304, and 404. The first power supply 510 may include a first power source 512, a first switch 514, and a first matcher 516. The first power source 512 may output first power. For example, the first power source may be an RF power supply. The first switch 514 may be disposed between the first power source 512 and the first, second, and third lower conductive plates 204, 304, and 404 to switch the delivery of the first power to the first, second, and third lower conductive plates 204, 304 and 404. The first matcher 516 may be disposed between the first power source 512 and the first switch 514 and may match the impedance between the first power source 512 and the first switch 514.

In example embodiments, the first switch 514 may be electrically connected to the first lower conductive plate 204 via a first lower conductive line 214. The first switch 514 may be electrically connected to the second lower conductive plate 304 via a second lower conductive line 314. The first switch 514 may be electrically connected to the third lower conductive plate 404 via a third lower conductive line 414. For example, the first, second, and third lower conductive plates 204, 304, and 404 may be independently connected to the first switch 514 via the first, second, and third lower conductive lines 214, 314, and 414. Thus, the first power output from the first power source 512 may be selectively provided to the first, second, and third lower conductive plates 204, 304, and 404 by the first switch 514.

Specifically, the first switch 514 may selectively connect the first power source 512 with the first lower conductive line 214 and the first power may be applied to the first lower conductive plate 204 allowing the first lower conductive plate 204 to operate as the lower electrode of the first dry cleaning module 200. When the first switch 514 does not connect the first power source 512 with the first lower conductive line 214, the first lower conductive plate 204 may operate as a ground for the first dry cleaning module 200.

When the first switch 514 connects the first power source 512 with the second lower conductive line 314, the first power may be applied to the second lower conductive plate 304 so that the second lower conductive plate 304 operates as the lower electrode of the second dry cleaning module 300. When the first switch 514 does not connect the first power source 512 with the second lower conductive line 314, the second lower conductive plate 304 may operate as the ground of the second dry cleaning module 300.

When the first switch 514 connects the first power source 512 with the third lower conductive line 414, the first power may be applied to the third lower conductive plate 404, so that the third lower conductive plate 404 operates as the lower electrode of the third dry cleaning module 400. When the first switch 514 does not connect the first power source 512 with the third lower conductive line 414, the third lower conductive plate 404 may operate as the ground of the third dry cleaning module 400.

The first switch 514 may be individually and selectively connected to the first, second, and third lower conductive plates 204, 304, and 404 via the first, second, and third lower conductive lines 214, 314, and 414 through a first guide 810. The first guide 810 is configured to individually receive the first, second, and third lower conductive lines 214, 314, and 414 and selectively distribute the first power to the first, second, and third lower conductive plates 204, 304, and 404. The first guide 810 may be disposed along a direction perpendicular to the outer peripheral surface of the first, second, third, and fourth supports 202, 302, 402, and 802. Thus, the first guide 810 may also support the first, second, third, and fourth supports 202, 302, 402, and 802.

The second power supply 520 may supply a second power to the first, second, and third upper conductive plates 208, 308, and 408. The second power supply 520 may include a second power source 522, a second switch 524, and a second matcher 526. The second power source 522 may output the second power, which may be RF power. For example, the second power source 522 may be an RF power supply. The second switch 524 may be disposed between the second power source 522 and the first, second, and third upper conductive plates 208, 308, and 408 to switch the provision of the second power to the first, second, and third upper conductive plates 208, 308, and 408. The second matcher 526 may be disposed between the second power source 522 and the second switch 524 and may match the impedance between the second power source 522 and the second switch 524. In example embodiments, the second power may be the same as the first power or may be a different power.

In example embodiments, the second switch 524 may be electrically connected to the first upper conductive plate 208 via a first upper conductive line 216. The second switch 524 may be electrically connected to the second upper conductive plate 308 via a second upper conductive line 316. The second switch 524 may be electrically connected to the third upper conductive plate 408 via a third upper conductive line 416. For example, the first, second, and third upper conductive plates 208, 308, and 408 may be connected to the second switch 524 via the independent first, second, and third upper conductive lines 216, 316, and 416. Thus, the second power output from the second power source 522 may be selectively provided to the first, second, and third upper conductive plates 208, 308, and 408 by the second switch 524.

Specifically, when the second switch 524 connects the second power source 522 with the first upper conductive line 216, the second power may be applied to the first upper conductive plate 208, so that the first upper conductive plate 208 operates as the upper electrode of the first dry cleaning module 200. When the second switch 524 does not connect the second power source 522 with the first upper conductive line 216, the first upper conductive plate 208 may operate as a ground for the first dry cleaning module 200.

When the second switch 524 connects the second power source 522 with the second upper conductive line 316, the second power may be applied to the second upper conductive plate 308, so that the second upper conductive plate 308 operates as the upper electrode of the second dry cleaning module 300. When the second switch 524 does not connect the second power source 522 with the second upper conductive line 316, the second upper conductive plate 308 may operate as the ground of the second dry cleaning module 300.

When the second switch 524 connects the second power source 522 with the third upper conductive line 416, the second power may be applied to the third upper conductive plate 408, which allows the third upper conductive plate 408 to operate as the upper electrode of the third dry cleaning module 400. When the second switch 524 does not connect the second power source 522 with the third upper conductive line 416, the third upper conductive plate 408 may operate as the ground of the third dry cleaning module 400.

The second switch 524 may be individually connected to the first, second, and third upper conductive plates 208, 308, and 408 via the first, second, and third upper conductive lines 216, 316, and 416 through a second guide 820. The second guide 820 may be configured to individually receive the first, second, and third upper conductive lines 216, 316, and 416 and distribute the second power between the first, second, and third upper conductive plates 208, 308, and 408. The second guide 820 may be disposed along a perpendicular direction to the outer peripheral surface of the first, second, third, and fourth supports 202, 302, 402, and 802. The second guide 820 may be spaced apart from the first guide 810, i.e., the first guide 810 and the second guide 820 may be located on different perpendicular plates. Thus, the second guide 820 may also support the first through fourth supports 202, 302, 402, and 802.

A reaction gas may be stored in a gas tank 600. The reaction gas may be supplied to the first, second, and third showerheads 210, 310, and 410 via gas lines. In particular, the reaction gas may be supplied to the first, second, and third showerheads 210, 310, and 410 individually via independent gas lines.

Specifically, a first gas line 602 may be connected between the gas tank 600 and the first showerhead 210. Thus, the reaction gas in the gas tank 600 may be introduced into the upper space between the first showerhead 210 and the first upper conductive plate 208 via the first gas line 602. A second gas line 604 may be connected between the gas tank 600 and the second showerhead 310. Thus, the reaction gas in the gas tank 600 may be introduced into the upper space between the second showerhead 310 and the second upper conductive plate 308 via the second gas line 604. A third gas line 606 may be connected between the gas tank 600 and the third showerhead 410. Thus, the reaction gas in the gas tank 600 may be introduced into the upper space between the third showerhead 410 and the third upper conductive plate 408 via the third gas line 606.

The reaction gases may be individually connected to the first, second, and third showerheads 210, 310, and 410 via the first, second, and third gas lines 602, 604, and 606, and the dry cleaning apparatus may include a third guide 830 configured to individually receive and control the flow rate of the first, second, and third gas lines 602, 604 and 606. The third guide 830 may be disposed along a perpendicular direction to an outer peripheral surface of the first, second, third, and fourth supports 202, 302, 402, and 802. The third guide 830 may be spaced about 180° from the first guide 810 relative to the center of the third support 402, but is not limited thereto. The third guide 830 may also support the first, second, third, and fourth supports 202, 302, 402, and 802.

The first, second, third, and fourth heaters 206, 306, 406, and 806 may be independently controlled by the controller 700. The first, second, third, and fourth heaters 206, 306, 406, and 806 may be connected to the controller 700 via first, second, third, and fourth heating lines 702, 704, 706, and 708. Specifically, a first heating line 702 may be connected between the first heater 206 and the controller 700. A second heating line 704 may be connected between the second heater 306 and the controller 700. A third heating line 706 may be connected between the third heater 406 and the controller 700. A fourth heating line 708 may be connected between the fourth heater 806 and the controller 700.

The first, second, third, and fourth heaters 206, 306, 406, and 806 may be individually connected to the controller 700 via the first, second, third, and fourth heating lines 702, 704, 706, and 708, and the dry cleaning apparatus may include a fourth guide 840 configured to individually receive the first, second, third, and fourth heating lines 702, 704, 706, and 708. The fourth guide 840 may be disposed along a perpendicular direction to the outer peripheral surface of the first, second, third, and fourth supports 202, 302, 402, and 802. The fourth guide 840 may be spaced about 180° from the second guide 820 relative to the center of the third support 402, but is not limited thereto. Additionally, the fourth guide 840 may be spaced from the third guide 830 by being located on a different perpendicular plane to the third guide 830. The fourth guide 840 may also support the first, second, third, and fourth supports 202, 302, 402, and 802.

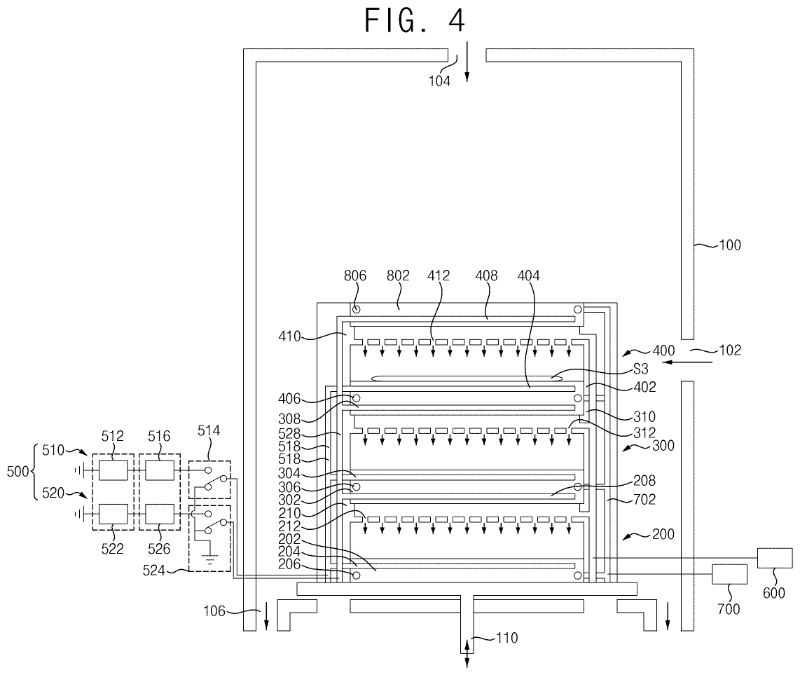

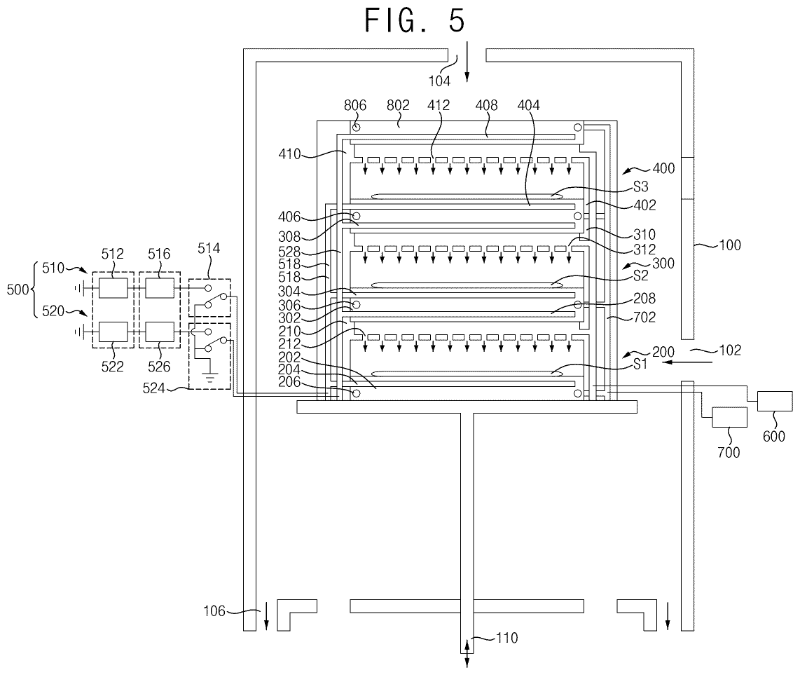

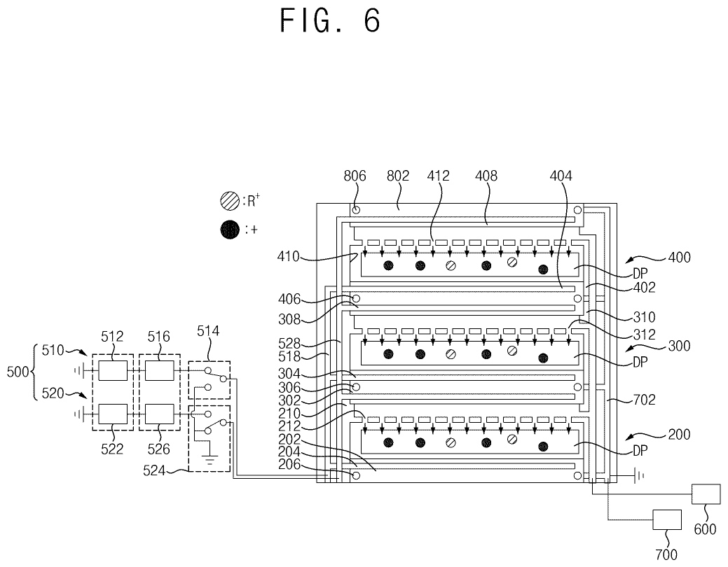

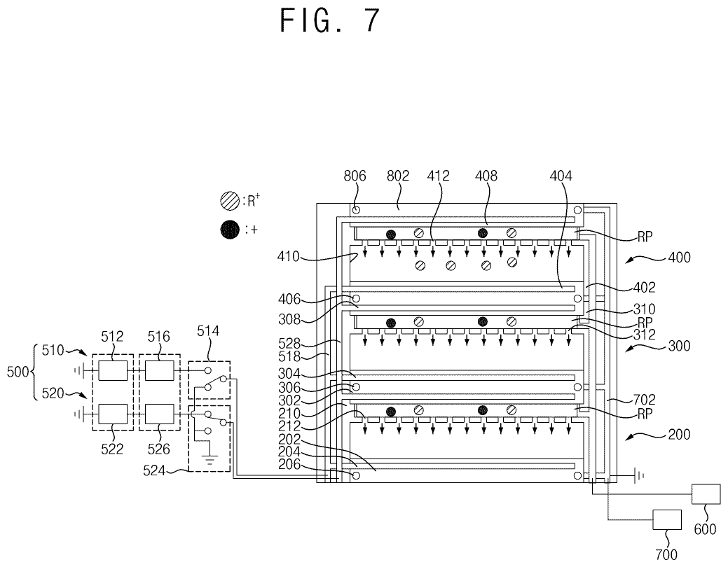

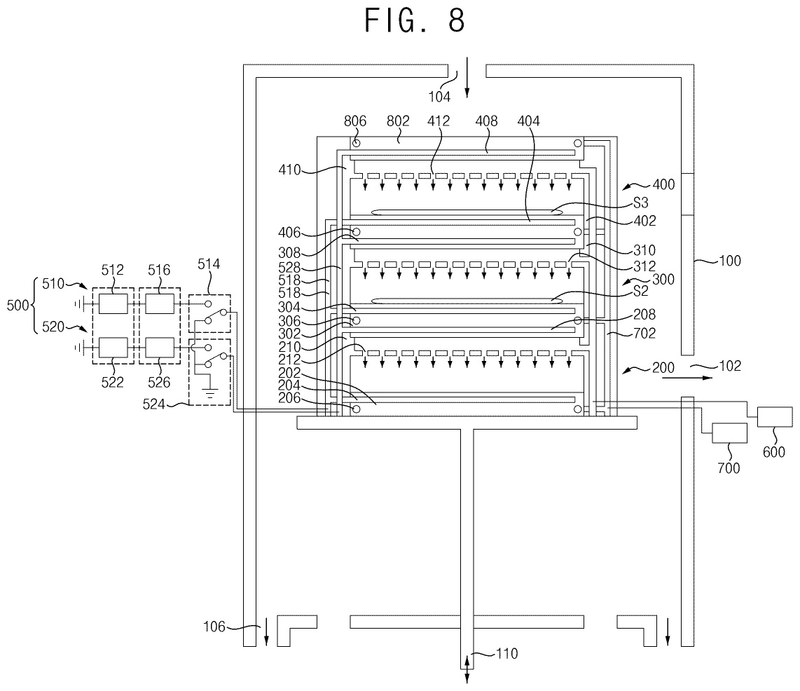

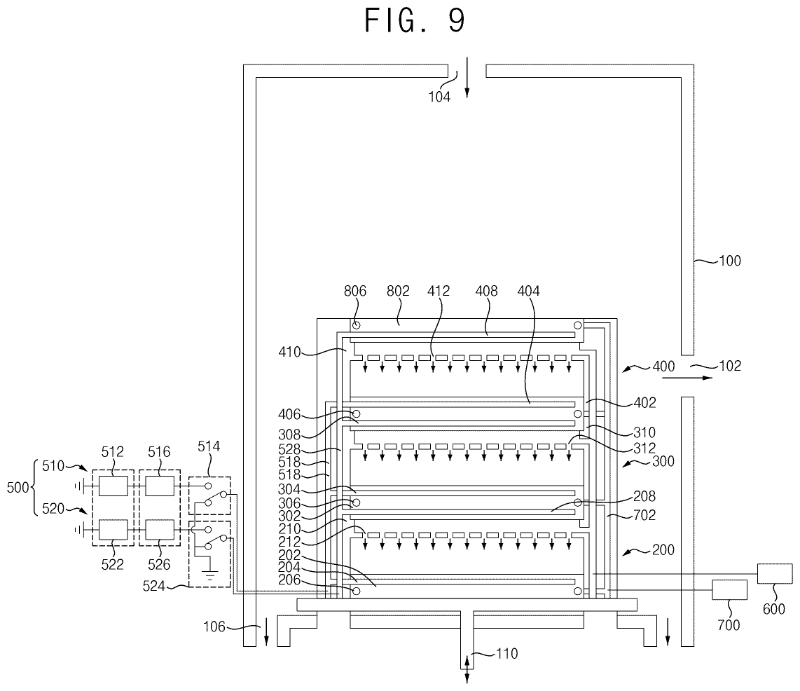

FIGS. 4 and 5 are schematic cross-sectional views illustrating an operation of loading substrates in the dry cleaning apparatus shown in FIG. 1, and FIG. 6 is a schematic cross-sectional view illustrating an operation for dry cleaning substrates using a direct plasma, FIG. 7 is a schematic cross-sectional view illustrating an operation of dry cleaning substrates using a remote plasma, and FIGS. 8 and 9 are schematic cross-sectional views illustrating an operation of unloading substrates in the dry cleaning apparatus shown in FIG. 1.

Referring to FIGS. 4 and 5, the lifter 110 may raise the first, second, and third dry cleaning modules 200, 300, and 400 to position the third dry cleaning module 400 at the substrate-loading height. The third semiconductor substrate S3 may be introduced into the third dry cleaning module 400 through the substrate entrance 102.

The lifter 110 may raise the first, second, and third dry cleaning modules 200, 300, and 400 to position the second dry cleaning module 300 at the substrate-loading height. The second semiconductor substrate S2 may be introduced into the second dry cleaning module 300 through the substrate entrance 102.

The lifter 110 may raise the first, second, and third dry cleaning modules 200, 300, and 400 to position the first dry cleaning module 200 at the substrate-loading height. The first semiconductor substrate S1 may be introduced into the first dry cleaning module 200 through the substrate entrance 102.

The first, second, and third semiconductor substrates S1, S2, and S3 may be dry cleaned using direct plasma (DP). When the first, second, and third semiconductor substrates S1, S2, and S3 are dry cleaned using direct plasma the first switch 514 may connect the first power source 512 to the first, second, and third lower conductive plates 204, 304, and 404, as shown in FIG. 6. Thus, the first power may be applied to the first, second, and third lower conductive plates 204, 304, and 404, and the first, second, and third lower conductive plates 204, 304, and 404 may operate as electrodes. The second switch 524 may disconnect the second power source 522 from the first, second, and third upper conductive plates 208, 308, and 408. Thus, the second power may not be applied to the first, second, and third upper conductive plates 208, 308, and 408, and the first, second, and third upper conductive plates 208, 308, and 408 may be grounded.

In this state, a reaction gas may be supplied to the first, second, and third showerheads 210, 310, and 410. The reaction gas may be injected through the first, second, and third injection holes 212, 312, and 412 of the first, second, and third showerheads 210, 310, and 410 into the lower spaces of the first, second, and third dry cleaning modules 200, 300, and 400. Since the first, second, and third lower conductive plates 204, 304, and 404 correspond to the electrodes, plasma may be formed in the lower spaces from the reaction gas due to an electric field generated by the first, second, and third lower conductive plates 204, 304 and 404. The plasma may be applied to the first, second, and third semiconductor substrates S1, S2, and S3 to dry clean the first, second, and third semiconductor substrates S1, S2, and S3, i.e., the ions and radicals in the plasma may clean the first, second, and third semiconductor substrates S1, S2, and S3.

The first, second, and third semiconductor substrates S1, S2, and S3 may be dry cleaned using remote plasma (RP) as shown in FIG. 7. When dry cleaning the first, second, and third semiconductor substrates S1, S2, and, S3 using remote plasma (RP), the first switch 514 may not connect the first power source 512 to the first, second, and third lower conductive plates 204, 304, and 404. Thus, the first power may not be applied to the first, second, and third lower conductive plates 204, 304, and 404, which may result in the first, second, and third lower conductive plates 204, 304, and 404 being grounded. The second switch 524 may connect the second power source 522 to the first, second, and third upper conductive plates 208, 308, and 408. Thus, the second power may be applied to the first, second, and third upper conductive plates 208, 308, and 408, and the first, second, and third upper conductive plates 208, 308, and 408 may operate as electrodes.

In this state, the reaction gas may be supplied to the first, second, and third showerheads 210, 310, and 410. Since the first, second, and third upper conductive plates 208, 308, and 408 correspond to the electrodes, plasma may be formed in the upper spaces from the reaction gas due to an electric field generated by the first, second, and third upper conductive plates 208, 308 and 408. The plasma may be applied to the first, second, and third semiconductor substrates S1, S2, and S3 through the first, second, and third injection holes 212, 312, and 412 to dry clean the first, second, and third semiconductor substrates S1, S2, and S3. Ions in the plasma may not be allowed to pass or may be substantially blocked from passing through the first, second, and third injection holes 212, 312, and 412, so that only radicals in the plasma or substantially only the radicals may clean the first, second, and third semiconductor substrates S1, S2, and S3.

Referring to FIGS. 8 and 9, the lifter 110 may lower the first, second, and third dry cleaning modules 200, 300, and 400 to position the first dry cleaning module 200 at the substrate-unloading height. The first semiconductor substrate S1 may be unloaded from the first dry cleaning module 200 through the substrate entrance 102.

The lifter 110 may lower the first, second, and third dry cleaning modules 200, 300, and 400 to position the second dry cleaning module 300 at the substrate-unloading height. The second semiconductor substrate S2 may be unloaded from the second dry cleaning module 300 through the substrate entrance 102.

The lifter 110 may lower the first, second, and third dry cleaning modules 200, 300, and 400 to position the third dry cleaning module 400 at the substrate-unloading height. The third semiconductor substrate S3 may be unloaded from the third dry cleaning module 400 through the substrate entrance 102.

According to these embodiments, the dry cleaning modules may receive the independent power from the power supply 500 so that each of the substrates may be drying cleaned under the same conditions. In particular, the upper and lower conductive plates may be selectively provided as an electrode or as a ground by the first and second power supplies, allowing for precise control of the plasma generated within the dry cleaning modules. As a result, the time to clean the substrates may be significantly reduced, which may improve the productivity of semiconductor devices.

While the foregoing has been described with reference to preferred embodiments of the invention, those skilled in the art will appreciate that various modifications and changes may be made to the invention without departing from the spirit of the invention as recited in the scope of the following patent claims.

What is claimed is:

1. A dry cleaning apparatus comprising:
a cleaning chamber;
at least two dry cleaning modules stacked in the cleaning chamber and configured to separately dry clean at least two substrates at the same time; and
a power supply that supplies power individually to the at least two dry cleaning modules to generate a plasma for dry cleaning each of the at least two substrates.

2. The dry cleaning apparatus of claim 1, wherein each of the at least two dry cleaning modules comprises:
a respective support having a respective support surface to support a respective substrate of the at least two substrates;
a respective lower conductive plate disposed in the respective support and selectively operable as an electrode or ground;
a respective heater disposed in the respective support to heat the respective substrate;
a respective showerhead disposed over the respective support, the respective showerhead having at least one respective injection hole for supplying a reaction gas for generating plasma; and
a respective upper conductive plate disposed over the respective showerhead and selectively operable as an electrode or ground,
wherein the power supply system selectively provides power to the respective lower conductive plate and the respective upper conductive plate to cause the respective lower conductive plate and the respective upper conductive plate to operate selectively as either an electrode or a ground.

3. The dry cleaning apparatus of claim 2, wherein the respective support comprises an insulating material and the respective showerhead comprises a conductive material.

4. The dry cleaning apparatus of claim 3, wherein a respective direct plasma region is formed between the respective support and the respective showerhead when the respective lower conductive plate operates as an electrode and the respective upper conductive plate operates as a ground.

5. The dry cleaning apparatus of claim 3, wherein a respective remote plasma region is formed between the respective showerhead and the respective upper conductive plate when the respective lower conductive plate operates as a ground and the respective upper conductive plate operates as an electrode.

6. The dry cleaning apparatus of claim 2, wherein the at least two dry cleaning modules each further comprise a respective second support and wherein the respective upper conductive plate is disposed in the respective second support.

7. The dry cleaning apparatus of claim 2, wherein the power supply comprises:
a first power supply configured to supply a first power to each respective lower conductive plate; and
a second power supply configured to supply a second power to each respective upper conductive.

8. The dry cleaning apparatus of claim 7, wherein the first power supply comprises:
a first power source that outputs the first power; and
a first switch disposed between the first power source and each respective lower conductive plate to switch the first power to each respective lower conductive plate.

9. The dry cleaning apparatus of claim 7, wherein the second power supply comprises:
a second power source that outputs the second power; and
a second switch disposed between the second power source and each respective upper conductive plate to switch the second power to each respective upper conductive plate.

10. The dry cleaning apparatus of claim 2, further comprising:
a first guide electrically connecting the power supply with at least one lower conductive plate;
a second guide electrically connecting the power supply with at least one upper conductive plate;
a third guide through which the reaction gas is supplied to at least one showerhead; and
a fourth guide connected to at least one heater.

11. The dry cleaning apparatus of claim 1, wherein the at least two dry cleaning modules are stacked vertically in the cleaning chamber.

12. The dry cleaning apparatus of claim 11, wherein the cleaning chamber comprises:
a substrate entrance for passing the at least two substrates into and out of the cleaning chamber;
a gas port that provides an inert gas to the at least two dry cleaning modules; and
an exhaust port that exhaust byproducts from the cleaning chamber.

13. The dry cleaning apparatus of claim 12, further comprising a lifter configured to elevate the at least two dry cleaning modules to position one of the at least two dry cleaning modules at the substrate entrance.

14. A dry cleaning apparatus comprising:
a cleaning chamber;
a first support disposed in the cleaning chamber and having a support surface to support a first substrate;
a first lower conductive plate disposed in the first support;
a first heater disposed in the first support to heat the first substrate;
a second support disposed in the cleaning chamber over the first support and having a second support surface to support a second substrate;
a first upper conductive plate disposed in the second support;
a second heater disposed in the second support to heat the second substrate;
a first showerhead disposed on a lower surface of the second support, wherein the first showerhead introduces a reaction gas for plasma formation between the first lower conductive plate and the first upper conductive plate through the first showerhead;
a second lower conductive plate disposed in the second support over the first upper conductive plate;
a second upper conductive plate disposed over the second lower conductive plate;
a second showerhead disposed under the second upper conductive plate, wherein the second showerhead introduces a reaction gas for plasma formation between the second lower conductive plate and the second upper conductive plate through the second showerhead;
a first power supply that selectively supplies a first power to the first lower conductive plate and the second lower conductive plate to cause the first and second lower conductive plates to selectively operate as one of an electrode and a ground; and
a second power supply that selectively supplies a second power to the first upper conductive plate and the second upper conductive plate to cause the first and second upper conductive plates to selectively operate as one of an electrode and a ground,
wherein when the first lower conductive plate and the second lower conductive plate operate as electrodes, the first upper conductive plate and the second upper conductive plate operate as the ground, and when the first lower conductive plate and the second lower conductive plate operate as the ground, the first upper conductive plate and the second upper conductive plate operate as electrodes.

15. The dry cleaning apparatus of claim 14, wherein the first power supply comprises:
a first power source that outputs the first power;
a lower conductive line electrically connecting the first power source to the first and second lower conductive plates; and
a first switch disposed that switches the first power to the first and second lower conductive plates.

16. The dry cleaning apparatus of claim 15, further comprising a first guide that receives the lower conductive line.

17. The dry cleaning apparatus of claim 14, wherein the second power supply comprises:
a second power source that outputs the second power;
an upper conductive line electrically connecting the second power source to the first and second upper conductive plates; and
a second switch that switches the second power to the first and second upper conductive plates.

18. The dry cleaning apparatus of claim 17, further comprising a second guide that receives the upper conductive line.

19. The dry cleaning apparatus of claim 14, further comprising a third support that receives the second upper conductive plate.

20. The dry cleaning apparatus of claim 14, further comprising:
a lifter configured to elevate the first support and the second support in the cleaning chamber.
